(19) United States
(12) Patent Application Publication
(10) Pub. No.: US 2017/0041987 A1
(43) Pub. Date: Feb. 9, 2017

(54) PANE WITH AN ILLUMINATED SWITCH SURFACE AND A HEATING FUNCTION

(71) Applicant: SAINT-GOBAIN GLASS FRANCE, Courbevoie (FR)

(72) Inventors: Patrick WEBER, ALSDORF (DE); Valentin SCHULZ, NIEDERZIER (DE); Francois HERMANGE, AACHEN (DE); Stefan DROSTE, HERZOGENRATH (DE); Jens BONDKOWSKI, PARIS (FR); Gerry PARIJ, WARREN, MI (US)

(21) Appl. No.: 15/303,494

(22) PCT Filed: Apr. 21, 2015
(86) PCT No.: PCT/EP2015/058552

§ 371 Date: Oct. 11, 2016

Related U.S. Application Data
(60) Provisional application No. 61/983,669, filed on Apr. 24, 2014.

(51) Int. Cl. H05B 3/84; H03K 17/96; B32B 17/10

(52) U.S. Cl. CPC H05B 3/84; B32B 17/10036; B32B 17/10761; B32B 17/10192; B32B 17/10385; B32B 17/10541; H03K 17/9622; H05B 2203/013; H05B 2203/014; B32B 2605/006; H03K 2217/960785; H03K 2217/960795

(57) ABSTRACT

A pane with an illuminated switch surface and a heating function is described. The pane includes a transparent substrate and a heating zone that is connected to at least two busbars intended for connecting to a voltage source, such that a current path for a heating current is formed between the busbars. The pane also includes an electrically conductive structure that forms a switch surface, and that can be connected to a sensor electronics assembly. Marking of the switch surface is provided by illumination means.

The invention relates to a pane with an illuminated switch surface and a heating function, a method for its production, and its use.

It is known that switch surfaces can be formed by a surface electrode or by an arrangement of two coupled electrodes, for example, as capacitive switch surfaces. When an object approaches the switch surface, the capacitance of the surface electrode changes against ground or the capacitance of the condenser formed by the two coupled electrodes changes. The capacitance change is measured by a circuit arrangement and when a threshold value is exceeded, a switching signal is triggered. Circuit arrangements for capacitive switches are known, for example, from DE 20 2006 006 192 U1, EP 0 899 882 A1, US 6,452,514 B1, and EP 1 515 211 A1.

The electrode or the electrodes can be applied directly on a pane made of glass or another transparent material, which is known, for example, from EP 1 544 178 A1. The switch surface can thus be integrated without any additional structural elements into a glazing. However, the switch surface is difficult or impossible to discern. Moreover, the switch surface cannot be felt in the dark. Consequently, the position of the switch surface must be identified, with the identification, in particular, having to be perceptible even in the dark.

The object of the present invention is to provide an improved pane with an integrated switch surface, illumination, and a heating function and a method for its production.

The object of the present invention is accomplished according to the invention by a pane with an illuminated switch surface in accordance with the independent claim 1. Preferred embodiments are apparent from the dependent claims.

The pane according to the invention with an illuminated switch surface comprises the following characteristics:
a transparent substrate,
a heating zone that is connected to at least two busbars intended for connecting to a voltage source such that a current path for a heating current is formed between the busbars,
an electrically conductive structure, which forms a switch surface and which can be connected to a sensor electronics assembly, and
an illumination means, with which the switch surface can be identified.

The transparent substrate preferably contains prestressed, partially prestressed, or non-prestressed glass, particularly preferably flat glass, float glass, quartz glass, borosilicate glass, soda lime glass, or clear plastics, in particular polyethylene, polypropylene, polycarbonate, polymethyl methacrylate, polystyrene, polyamide, polyester, polyvinyl chloride, and/or mixtures thereof.

The thickness of the substrate can vary widely and thus be ideally adapted to the requirements of the individual case. The substrate preferably has a thickness from 0.7 mm to 10 mm and particularly preferably from 1 mm to 5 mm. The area of the substrate can vary widely, for example, from 100 cm² to 18 m². Preferably, the substrate has an area from 400 cm² to 4 m², as is common for motor vehicle glazings and for structural and architectural glazings.

In an advantageous embodiment of a pane according to the invention, the substrate is part of a composite pane, in particular of a laminated safety glass. The substrate is bonded via at least one intermediate layer to at least one cover pane. The intermediate layer preferably contains at least one thermoplastic plastic, preferably polyvinyl butyral (PVB), ethylene vinyl acetate (EVA), and/or polyethylene terephthalate (PET). However, the thermoplastic intermediate layer can also contain, for example, polyurethane (PU), polypropylene (PP), polyacrylate, polyethylene (PE), polycarbonate (PC), polymethyl methacrylate, polyvinyl chloride, polyacetate resin, casting resins, acrylates, fluorinated ethylene propylene, polyvinyl fluoride, and/or ethylene tetrafluoroethylene, or copolymers or mixtures thereof. The thermoplastic intermediate layer can be formed by one or even by a plurality of thermoplastic films arranged one above the other, with the thickness of one thermoplastic film preferably from 0.25 mm to 1 mm, typically 0.38 mm or 0.76 mm.

The cover pane preferably contains prestressed, partially prestressed, or non-prestressed glass, particularly preferably flat glass, float glass, quartz glass, borosilicate glass, soda lime glass, or clear plastics, in particular polyethylene, polypropylene, polycarbonate, polymethyl methacrylate, polystyrene, polyamide, polyester, polyvinyl chloride, and/or mixtures thereof. The cover pane preferably has a thickness from 0.3 mm to 10 mm and particularly preferably from 0.7 mm to 3 mm.

In the context of the invention, a pane, a substrate, a cover pane, or a layer is “transparent” when the transmittance in the visible spectral range is greater than 70%. For panes that are not within the traffic-relevant field of vision of the driver, for example, for roof panels, the transmittance can, however, even be much lower, for example, greater than 5%.

The heating zone is connected to at least two busbars intended for connecting to a voltage source such that a current path for a heating current is formed between the busbars.

In an advantageous embodiment of a heating zone according to the invention, the heating zone has a plurality of individual metal wires, so-called “heating wires”, which connect the busbars to each other in each case. The current paths and the heating current run along the individual wires. The wires are advantageously implemented very thin such that they impair the view through the pane only slightly or not at all. Preferred wires have a thickness less than or equal to 0.1 mm, particularly preferably from 0.02 mm to 0.04 mm, and in particular from 0.024 mm to 0.029 mm. The metal wires preferably contain copper, tungsten, gold, silver, or aluminum or alloys of at least two of these metals. The metal wires are particularly preferably made of copper, tungsten, gold, silver, or aluminum or alloys of at least two of these metals. The alloys can also contain molybdenum, rhenium, osmium, iridium, palladium, or platinum.

In an alternative advantageous embodiment of the pane according to the invention, the heating zone contains thin, printed heating structures made of an electrically conductive material, for example, a fired printing paste with metal particles.

In another alternative advantageous embodiment of a heating zone according to the invention, the heating zone has a transparent, electrically conductive layer. In particular, the heating zone can be part of a transparent, electrically conductive layer, which, for example, also includes other electrically conductive structures that are electrically isolated from the heating zone.

The electrically conductive layer preferably contains a transparent, electrically conductive coating. Electrically conductive layers according to the invention are known, for example, from DE 20 2008 017 611 U1, EP 0 847 965 B1, or WO2012/052315 A1. They typically contain one or a plurality, for example, two, three, or four electrically conductive, functional layers. The functional layers preferably contain at least one metal, for example, silver, gold, copper, nickel and/or chromium, or a metal alloy. The functional layers particularly preferably contain at least 90 wt.-% of the metal, in particular at least 99.9 wt.-% of the metal. The functional layers can be made of the metal for the metal alloy. The functional layers particularly preferably contain silver or a silver-containing alloy. Such functional layers have particularly advantageously electrical conductivity and, at the same time, high transmittance in the visible spectral range. The thickness of a functional layer is preferably from 5 nm to 50 nm, particularly preferably from 8 nm to 25 nm. in this range for the thickness of the functional layer, advantageously high transmittance in the visible spectral range and particularly advantageous electrical conductivity are obtained.

Typically, at least one dielectric layer is arranged in each case between two adjacent functional layers of the heatable coating. Preferably, another dielectric layer is arranged below the first and/or above the last functional layer. A dielectric layer contains at least one individual layer made of a dielectric material, for example, containing a nitride such as silicon nitride or an oxide such as aluminum oxide. Dielectric layers can, however, also contain a plurality of individual layers, for example, individual layers of a dielectric material, smoothing layers, matching layers, blocker layers, and/or antireflection layers. The thickness of a dielectric layer is, for example, from 10 nm to 200 nm.

This layer structure is generally obtained by a sequence of deposition operations that are performed by a vacuum method such as magnetic field-supported cathode sputtering.

Other suitable electrically conductive layers preferably contain indium tin oxide (ITO), fluorinated tin oxide (SnO₂:F), or aluminum-doped zinc oxide (ZnO:Al).

The electrically conductive layer can, in principle, be any coating that can be contacted electrically. If the pane according to the invention is intended to enable vision through it, such as is the case, for example, for panes in the window area, the electrically conductive layer is preferably transparent. In an advantageous embodiment, the electrically conductive layer is a layer or a layer structure of a plurality of individual layers with a total thickness less than or equal to 2 μm, particularly preferably less than or equal to 1 μm.

An advantageous electrically conductive layer according to the invention has a sheet resistance from 0.4 ohm/square to 10 ohm/square. In a particularly preferred embodiment, the electrically conductive layer according to the invention has a sheet resistance from 0.5 ohm/square to 1 ohm/square. Coatings with such sheet resistances are particularly suited for heating the motor vehicle window panes with typical onboard voltages from 12 V to 48 V or, in the case of electric vehicles, with typical onboard voltages of as much as 500 V.

The electrically conductive layer can extend over the entire surface of the substrate. However, alternatively, the electrically conductive layer can extend over only a part of the surface of the substrate. The electrically conductive layer preferably extends over at least 50%, particularly preferably over at least 70%, and most particularly preferably over at least 90% of the interior-side surface of the substrate. The electrically conductive layer can have one or a plurality of uncoated zones. These zones can be transparent to electromagnetic radiation and are known, for example, as a data transmission windows or communication windows.

In an advantageous embodiment of a pane according to the invention as a composite pane, the interior-side surface of the substrate has a circumferential edge region with a width from 2 mm to 50 mm, preferably from 5 mm to 20 mm, which is not provided with the electrically conductive layer. The electrically conductive layer in this case has no contact with the atmosphere and is advantageously protected in the interior of the pane by the thermoplastic intermediate layer against damage and corrosion.

The heating zone has at least two busbars intended for connecting to a voltage source and is connected to them such that, between the busbars, a current path for a heating current is formed and, in particular, a heating current flows when a voltage is applied.

The busbars are preferably arranged along the lateral edge of the electrically conductive layer. The length of the busbar is typically substantially equal to the length of the lateral edge of the electrically conductive layer; however, it can also be slightly larger or smaller. Even more than two busbars can be arranged on the electrically conductive layer, preferably in the edge region along two opposing lateral edges of the electrically conductive layer. Even more than two busbars can be arranged on the electrically conductive layer, for example, in order to form two or more uncoated heating zones in one layer or when the busbar is interrupted or displaced by one or a plurality of uncoated zones such as communication windows. The teaching according to the invention then applies to at least one and preferably to each of the independent heating zones.

In an advantageous embodiment, the busbar according to the invention is implemented as a printed and fired conductive structure. The printed busbar preferably contains at least one metal, one metal alloy, one metal compound, and/or carbon, particularly preferably one noble metal and, in particular, silver. The printing paste preferably contains metallic particles, metal particles, and/or carbon and, in particular noble metal particles such as silver particles. The electrical conductivity is preferably achieved by means of the electrically conductive particles. The particles can be situated in an organic and/or inorganic matrix such as pastes or inks, preferably as printing paste with glass frits.

The width of the first and second busbars is preferably from 2 mm to 30 mm, particularly preferably from 4 mm to 20 mm and in particular from 10 mm to 20 mm. Thinner busbars result in excessively high electrical resistance and thus in excessively high heating of the busbars during operation. Moreover, thinner busbars are relatively difficult to produce by printing techniques such as screenprinting. Thicker busbars require undesirably high use of material. Moreover, they result in excessively great and inaesthetic limitation of the see-through zone of the pane. The length of the busbar is governed by the dimension of the heating zone. In the case of a busbar, which is typically implemented in the shape of a strip, the longer of its dimensions is referred to as “length” and the less long of its dimensions is referred to as “width”. The third or additional busbars can be configured even thinner, preferably from 0.6 mm to 5 mm.

The layer thickness of the printed busbars is preferably from 5 μm to 40 μm, particularly preferably from 8 μm to 20 μm and most particularly preferably from 8 μm to 12 μm. Printed busbars with these thicknesses are technically easy to realize and have advantageous current-carrying capacity.

The specific resistance ρₐ of the busbars is preferably from 0.8 μohm·cm to 7.0 μohm·cm and particularly preferably from 1.0 μohm·cm to 2.5 μohm·cm. Busbars with specific resistances in this range are technically easy to realize and have advantageous current-carrying capacity.

Alternatively, however, the busbar can also be implemented as a strip of an electrically conductive foil. The busbar then contains, for example, at least aluminum, copper, tinned copper, gold, silver, zinc, tungsten, and/or tin or alloys thereof. The strip preferably has a thickness from 10 μm to 500 pμm, particularly preferably from 30 μm to 300 μm. Busbars made of electrically conductive foils with these thicknesses are technically easy to realize and have advantageous current-carrying capacity. The strip can be electrically conductively connected to the electrically conductive structure, for example, via a soldering compound,

The pane according to the invention advantageously includes a substrate, on which a heatable electrically conductive layer is arranged. Depending on the type of layer, it is advantageous to protect the layer with a protective layer, for example, a lacquer, a polymer film, and/or a cover pane.

In an advantageous embodiment of the pane according to the invention, the electrically conductive structure contains at least one linear, electrically conductive element. The linear, electrically conductive element is preferably an electrically conductive wire. The wire is advantageously implemented very thin such it does not or only slightly impair vision through the pane. Preferred wires have a thickness less than or equal to 0.25 mm, particularly preferably from 0.02 mm to 0.15 mm. The wires are preferably metallic, contain in particular copper, tungsten, gold, silver, or aluminum or alloys of at least two of these metals or are made therefrom. The alloys can also contain molybdenum, rhenium, osmium, iridium, palladium, or platinum.

The wire is preferably electrically insulated, for example, by sheathing electrical insulation made of plastic. This is particularly advantageous if the wire runs on the electrically conductive layer or other electrically conductive and/or touches voltage-carrying elements of the pane.

In an alternative advantageous embodiment of the pane according to the invention, the electrically conductive structure contains at least one thin printed structure made of a conductive material, for example, a fired printing paste with metal particles. The electrically conductive structure can be produced by printing and firing a conductive paste. The conductive paste preferably contains silver particles and glass frits. The layer thickness of the fired paste is preferably from 5 μm to 40 μm, particularly preferably from 8 μm to 20 μm. the fired silver paste itself has light scattering properties and can, consequently, itself serve as a light deflection means.

In an alternative advantageous embodiment of the pane according to the invention, the electrically conductive structure contains a transparent, electrically conductive layer. This is particularly advantageous since, then, the electrically conductive structure impairs vision through the pane only slightly or not all. Various suitable transparent, electrically conductive layers were already mentioned in the introduction as layers for the heating zone.

Since the electrically conductive structure of the switch surface has to transport only low currents, the sheet resistance of the layer can be selected higher than the electrically conductive layer of the heating zone. An advantageous electrically conductive layer according to the invention for the switch surface has a sheet resistance from 0.4 ohm/square to 200 ohm/square.

In a particularly advantageous embodiment of a pane according to the invention, the electrically conductive structure of the switch surface and the heating zone are parts of the same electrically conductive layer and are electrically partitioned from the transparent, electrically conductive layer by at least one dividing line. The width d1 of the dividing lines is preferably from 30 μm to 200 μm and particularly preferably from 70 μm to 140 μm. Such thin dividing lines permit a safe and adequately high, electrical insulation and, at the same time, disrupt vision through the pane only slightly or not all. The production of the dividing lines is preferably done by laser patterning or chemical or mechanical removal. Such an arrangement of switch surface and heating zone made from the same layer is particularly simple and economical to produce.

The electrically conductive structure of the switch surface preferably has an area from 1 cm² to 200 cm², particularly preferably from 1 cm² to 10 cm². The switch surface can, for example, have the shape of an oval, an ellipse or a circle, a triangle, a rectangle, a square, or another type of quadrilateral or a higher polygon. In particular, circular, elliptical, or drop-shaped forms or forms with rounded corners as well as strip shapes are especially advantageous since the heating current can be particularly advantageously conducted around the peripheral zone and either very few or no local hot spots occur.

The switch surface can be electrically connected to a sensor electronics assembly, in particular galvanically, capacitively, and/or inductively.

In an advantageous embodiment of the pane according to the invention, the switch surface is a capacitive switch surface. In that case, the switch surface forms surface electrode. The capacitance of the surface electrode is measured by an external capacitive sensor electronics assembly. The capacitance of the surface electrode changes against ground when a grounded body comes into its proximity or, for example, touches an insulator layer over the surface electrode. The insulator layer comprises, in particular, the substrate itself or sensor electronics assembly, and when a threshold value is exceeded, a switching signal is triggered. The switch zone is defined by the shape and size of the surface electrode.

In an alternative embodiment of a pane according to the invention, the switch surface has two electrically conductive structures. In the case of an electrically conductive structure made of an electrically conductive layer, the layer is advantageously divided by one or a plurality of other dividing lines. It is particularly advantageous if the second electrically conductive structure borders the first electrically conductive structure at least partially and preferably completely. Such bordering is advantageous since, the influence of the heating zone and, in particular, a voltage change in the heating zone on the switch surface is thus reduced.

In another advantageous embodiment of the pane according to the invention, the surrounding zone has the same shape or a shape similar to the switch zone. In particular, circular, elliptical, or drop-shaped forms or forms with rounded corners as well as strip shapes are especially advantageous since the heating current can be particularly advantageously conducted around the peripheral zone and either very few or no local overheating areas, so-called “hot spots”, occur.

It is particularly advantageous for the second electrically conductive structure to have another connection zone that can be connected to the sensor electronics assembly. In such an arrangement, the first and second electrically conductive structure forms two electrodes that are capacitively coupled to each other. The capacitance of the capacitor formed by the electrodes changes with the proximity of a body, for example, a part of a human body. The change in capacitance is measured by a sensor electronics assembly and when a threshold value is exceeded, a switch signal is triggered. The sensitive zone is defined by the shape and size of the zone in which the electrodes are capacitively coupled.

Alternatively, the switch surface can also have inductive, thermal, or all other sensor functions that are contact free. “Contact free” means that no direct touching of the electrically conductive structure is necessary to trigger a switch operation. Of course, the switch function is also effective with direct touching of the electrically conductive structure, if the electrically conductive structure is accessible to the user. In principle, even switch surfaces with contact-dependent sensor functions can be implemented.

In an advantageous embodiment of the pane according to the invention, the electrically conductive structure, which forms the switch surface, can have three functionality different zones: a touch zone, a connection zone, which has an electrical line connection, to which the electrically conductive structure is electrically conductively connected toward the outside, and a supply line zone, which electrically conductively connects the touch zone to the connection zone. The touch zone is preferably implemented larger than the supply line zone. A sensor electronics assembly connected to the electrically conductive structure can, for example, be selected in its sensitivity such that only upon touching one of the pane surfaces in the region of the touch zone by a person, a switching signal is emitted; in contrast, a touching of the pane surfaces above the supply line zone triggers no switching signal. This can, alternatively or additionally, be optimized by a suitable selection of the geometries of the touch zone and the supply line zone. For example, the supply line zone can have a low width and a large length; whereas, in contrast, the touch zone is preferably implemented approx. square, round, circular, or drop-shaped and thus has a large touchable area, for example, for one or a plurality of human fingers or a hand surface.

The switch surface is integrated into the pane according to the invention. Thus, no switch is necessary as a separate component that has to be applied on the pane. The pane according to the invention, which can be implemented as an individual pane or as a composite pane, preferably also has no other components that are arranged on its surfaces in the see-through zone. This is particularly advantageous with regard to a thin design of the pane as well as only slight disruption of the vision through the pane.

An advantageous aspect of the invention comprises a pane arrangement with a pane according to the invention and a sensor electronics assembly, which is electrically connected via the connection zone to the switch surface and, optionally, via another connection zone to the surrounding surface. The sensor electronics assembly is preferably a capacitive sensor electronics assembly.

The pane according to the invention includes an illumination means, with which the switch surface can be identified. This is particularly advantageous, especially in the case of transparent, non-visible, or hardly visible switch surfaces, as this makes it possible to touch the switch surface with certainty and to trigger the switch operation with certainty. The illumination is advantageous, in particular, at night or in darkness as this makes it possible to invention as a motor vehicle pane, it is very simply possible for the driver to find and touch the switch surface without being distracted too long from the traffic situation.

The term “illumination means” is understood here to be a light source or a light deflection means that is arranged in the surroundings of the switch surface or a subsection of the switch surface as a touch zone and identifies it. The light deflection means can be illuminated by a light source that is arranged away from the light deflection means in or on the pane. To amplify the effect, the light source and the light deflection means can also be arranged in the same location or in the immediate vicinity of one another.

In an advantageous embodiment of the pane according to the invention, the illumination means includes a light source, preferably a light emitting diode (LED), an organic light emitting diode (OLED), an incandescent bulb, or other active luminary, such as a luminescent material, preferably a fluorescent or phosphorescent material.

In particular, the light source is arranged in the immediate vicinity of the switch surface such that the switch surface thus becomes recognizable for the user. Here, “the immediate vicinity” preferably means at a distance of up to 10 cm, particularly preferably from 0 cm to 3 cm.

In a particularly advantageous embodiment of the pane according to the invention, the light source is arranged on one of the surfaces of the substrate or in a recess of the substrate. In the case of a composite glass pane according to the invention, the light source can also be arranged on one of the surfaces of the intermediate layer or of the cover pane or in a recess of the intermediate layer or the cover pane.

Illumination means thus arranged in the form of a light source have the particular advantage of being particularly bright.

In these cases, the light source can be electrically contacted using thin wires, in particular thin metal wires with an electrically insulating sheathing. Alternatively, the light source can be electrically contacted via printed structures made of an electrically conductive material such as a silver printing paste.

In another alternative, the light source can be electrically contacted by zones of an electrically conductive layer, with the zones preferably separated from the surrounding electrically conductive layer by dividing lines. The electrically conductive layer can also be part of the electrically conductive structure of the switch zone or part of the heating zone.

In an alternative embodiment of a pane according to the invention, the illumination means is implemented as a light deflection means that is illuminated by a remotely arranged light source in, on, or outside the pane.

The illumination means identifies the position of the switch surface by a illuminating or illuminatable surface relative to the switch surface. The illumination means and the switch surface can be arranged in spatially distinct planes. Here, the term “plane” refers to a surface that is formed parallel to the surface of the pane. According to the invention, the illumination means is arranged such that the surface that results from the projection of the illumination means onto the plane of the switch surface is arranged inside the switch surface and/or continuously or discontinuously borders the switch surface. An orthogonal projection of the illumination means is carried out wherein the projection plane is the same plane in which the switch surface is arranged. The projection plane can also be spanned by a curved surface, in particular in the case of a curved pane according to the invention.

The surface area of the surface that results from a projection of the light deflection means onto the plane of the switch surface is preferably from 5% to 300%, particularly preferably from 10% to 200%, and most particularly preferably from 20% to 150% of the surface area of the switch surface. This is particularly advantageous with regard to a clear and unambiguous indication of the position of the switch surface on the pane according to the invention by light scattered on the light deflection means.

The surface that results from the projection of the illumination means onto the plane of the switch surface can be arranged completely within the switch surface. The surface area of the surface that results from the projection of the light deflection means onto the plane of the switch surface is preferably smaller than the surface area of the switch surface. Thus, the position of the switch surface is advantageously identified by the lighted surface on the pane, with even touching the pane in a region adjacent the lighted area still resulting in the triggering of a switch operation.

Alternatively, the surface area of the surface that results from the projection of the elimination means onto the plane of the switch surface can be equal to the surface area of the switch surface. The surface that results from the projection of the illumination means onto the plane of the switch surface and the switch surface are preferably identical or virtually identical. Thus, the position of the switch surface is advantageously identified by the lighted surface on the pane. Touching the lighted surface on the pane results in the triggering of a switch operation.

In an alternative advantageous embodiment of the invention, the surface area of the surface that results from the projection of the illumination means onto the plane of the switch surface is greater than the surface area of the switch surface. A first zone of the surface that results from the projection of the illumination means onto the plane of the switch surface preferably completely overlaps the switch surface. A second zone of the surface that results from the projection of the illumination means onto the plane of the switch surface borders the switch surface. Since, to trigger a switch operation, a user intuitively touches the inner zone of the lighted surface on the pane, the position of the switch surface is advantageously identified.

In an alternative advantageous embodiment of the invention, the switch surface is bordered by the surface that results from the projection of the illumination means onto the plane of the switch surface. The border can be designed continuous or discontinuous and can have, for example, a width from 0.2 cm to 2 cm, roughly 1 cm. The surface that results from the projection of the illumination means onto the plane of the switch surface and the switch surface do not overlap each other or only overlap in the edge region of the switch surface.

Since, to trigger a switch operation, a user intuitively touches the region on the pane bordered by the lighted surface, the position of the switch surface is advantageously identified.

In an alternative advantageous embodiment, the illumination means comprises a first and a second zone that are not connected to each other. The surface that results from the projection of the first zone of the illumination means onto the plane of the switch surface borders the switch surface continuously or discontinuously. The surface that results from the projection of the second zone of the illumination means onto the plane of the switch surface is arranged completely within the switch surface. The first zone of the illumination means can, for example, be formed as a circumferential circular edge. The second zone of the light deflection means can, for example, be formed as a symbol or a pictogram. Thus, the position of the switch surface is advantageously identified by the lighted surface on the pane.

In an advantageous embodiment of the pane according to the invention, the light of the light source is coupled in via the lateral edge of the substrate into the pane according to the invention. The light of the light source thus enters via the lateral edge of the substrate into the pane according to the invention. A zone of the pane is irradiated by the coupled-in light. The zone of the pane irradiated by the light is determined by the radiation characteristic of the light irradiation means. The substrate typically has a higher refractive index than the surroundings of the pane. The coupled-in light is reflected on the surfaces of the substrate according to the principle of total reflection into the interior of the substrate. Alternatively, the coupled-in light is totally reflected on the surfaces of further layers connected to the substrate facing away from the substrate, which have a refractive index similar to that of the substrate, and reflected into the interior of the pane. Light that strikes the light deflection means at the time of passage through the pane is not totally reflected, but, instead, leaves the pane, preferably by scattering on the light deflection means. The zone of the light deflection means is, consequently, perceived by an observer as a lighted surface on the pane.

Of course, the light source can equally couple light into the lateral edge of the cover pane or of the intermediate layer and an appropriately arranged light deflection means can couple this light out again.

The light deflection means preferably comprises structures for light scattering. These structures are particularly preferably particles, point grids, stickers, deposits, indentations, scratches, line grids, imprints, and/or silkscreen prints. The light deflection means can form a single continuous area. Alternatively, the light deflection means can form two or more areas separated from each other.

The light deflection means can have any desired shape that is suited for identifying the position of the switch surface. The light deflection means can, for example, have a simple two-dimensional geometric shape such as a circle, an ellipse, a triangle, a rectangle, a square or any other type of quadrilateral, a higher polygon, or combinations thereof. The geometric figure can be filled over its entire surface with the light deflection means. Alternatively, the light deflection means can be arranged along the edge of the geometric figure continuously or discontinuously. The light deflection means can even have a shape that describes the function that is controlled by the switch, for example, a “plus” or “minus” sign, one or a plurality of letters and/or numbers or a pictogram. The light deflection means can also have the shape of another graphic symbol, for example, a company or trademark symbol. The light deflection means can also have a shape that results from a combination of the examples mentioned, for example, a circumferential circular edge around a pictogram.

In an advantageous embodiment of the invention, the substrate is a single-plane safety glass. The electrically conductive structure can be arranged on the same surface of the substrate as the illumination means and, in particular, a light deflection means. The electrically conductive structure can be arranged out of the direction of the substrate above or below the light deflection means or in the same plane as the light deflection means. Alternatively, the electrically conductive structure and the light deflection means can be arranged on the opposite surfaces of the substrate.

Other layers can be arranged between the substrate and the electrically conductive structure, between the substrate and the illumination means, and/or between the electrically conductive structure and the illumination means. Other layers can be arranged on the side of the electrically conductive structure or the illumination means facing away from the substrate, for example, for protection against damage. The electrically conductive structure and/or the light deflection means can also be applied on a carrier film bonded to the substrate.

The transparent, electrically conductive layer, the electrically conductive structure, the light source, and/or the light deflection means can be applied on a carrier film. The carrier film preferably contains at least one polyester and/or one polyimide, particularly preferably a thermoplastic polyester, for example, polyethylene naphthalate (PEN) or polyethylene terephthalate (PET). This is particularly advantageous with regard to the stability and workability of the carrier film. In a particularly preferred embodiment, the electrically conductive structure and the light deflection means are applied on the carrier film. The particular advantage resides in a simple common positioning of the electrically conductive structure and the light deflection means during the production of the laminated safety glass. The carrier film is arranged between the substrate and the cover pane. The carrier film with the transparent, electrically conductive layer, the electrically conductive structure, the light source, and/or the light deflection means is particularly preferably bonded to the substrate via at least one first intermediate layer and to the cover pane via at least one second intermediate layer. The thickness of the carrier film is preferably from 10 μm to 1 mm, particularly preferably from 30 μm to 200 μm. In this range of thickness, the carrier film is equal to the length and width of the substrate. The length and width of the carrier film can also be smaller than the length and width of the substrate.

The pane according to the invention preferably has a transparent see-through zone. This means that an observer can perceive objects through the see-through zone of the pane. The switch surface as well as the illumination means are preferably arranged in the see-through zone of the pane. Preferably, no large area opaque components are arranged in the see-through zone. The flat conductor is preferably arranged completely outside the see-through zone of the pane. Thus, vision through the pane is not impaired by the flat conductor.

The contacting of the busbars, the light source, and/or the electrically conductive structure of the switch surface is preferably done via flat conductors. The electrically conductive core of the flat conductor is preferably made of a strip of a metal or an alloy, for example, of copper, tinned copper, aluminum, gold, silver, and/or tin. The strip preferably has a thickness from 0.3 mm to 0.2 mm, for example, 0.1 mm, and a width from 2 mm to 16 mm. The insulating sheathing preferably contains plastic and is made, for example, of a plastic film with a thickness from 0.025 mm to 0.05 mm.

The electrically conductive structure is preferably electrically connected to the flat conductor. The electrically conductive structure is preferably connected at least to an external sensor or control electronics assembly via the flat conductor. The sensor electronics assembly is adapted to the respective use and can, in the triggering of a switch operation, trigger, for example, a mechanism for opening or closing a door or heating the pane.

The electrical connection between the flat conductor and each electrode formed by the electrically conductive structure is made, according to the invention, via a connection zone as an electrical connecting element. The flat conductor is connected via an electrical line connection to the connection zone of the switch surface preferably by soldering, clamping, or by means of an electrically conductive adhesive. Thus, in a manner that is simple and hardly visible to the user, the contacts can be guided out of the pane or away from the pane.

The flat conductor is preferably connected to the connection zone in the edge region of the pane and can, for example, be masked by a frame, other fastening elements, or by a masking screenprint. The edge zone of the pane, in which the flat conductor is electrically conductively connected to the connection zone, preferably has a width less than or equal to 10 cm, particularly preferably less than or equal to 5 cm. The flat conductor runs from the edge zone of the pane beyond the lateral edge of the pane away from the pane, in order to be connected to the sensor electronics assembly. The flat conductor thus overlaps the surface of the substrate along a length of preferably a maximum of 10 cm, particularly preferably a maximum of 5 cm, for example, from 1 cm to 5 cm or from 2 cm to 3 cm. Thus, vision through the pane is advantageously little disrupted by the flat conductor. Of course, a light source can be similarly connected, for example, to a flat conductor, and thus, for example, be connected to an external voltage supply or control electronics assembly.

If the electrically conductive structure forms two electrodes coupled together, each electrode has a connection zone that can be connected to a flat conductor. In this case, the flat conductor preferably comprises two electrically conductive cores separated from each other that are enclosed in a common electrically insulating sheathing. The two electrical connecting elements are respectively connected with one electrically conductive core of the flat conductor. Alternatively, two flat conductors can be used for contacting the two electrical connection elements.

Another aspect of the invention relates to a pane arrangement comprising:
a pane according to the invention with an illuminated switch surface and a heating function,
at least one sensor electronics assembly as well as at least one voltage source that is connected to the switch surface, the heating zone, and the illumination means, wherein the sensor electronics assembly is implemented such that upon a touch of the switch surface by a person, a switch signal is sent to the control of the heating function. It is particularly advantageous for the illumination of the switch zone to display the switching state of the heating function, for example, heating function ON or “OFF”. This can, for example, occur by means of a change in the color of the illumination means (for example, by a change in the color of the light source) or by a change in the position of the lighted illumination means.

The invention further includes a method for producing a pane with an illuminated switch surface and a heating function, comprising at least:
Applying an electrically conductive layer on a surface (III) of a transparent substrate,
Introducing at least one dividing line that electrically partitions the layer into at least one heating zone and one switch surface,
Applying at least two bus bars intended for connecting to a voltage source that are connected to the layers such that a current path for a heating current is formed between the busbars, and
Arranging an illumination means, with which the switch surface can be identified, at least in sections.

Of course, the process steps can occur in any suitable sequence, wherein the electrically conductive layer is applied on the substrate and the dividing lines are introduced into the electrically conductive layer in one of the following steps.

The application of the electrically conductive layer can be done by methods known per se, preferably by magnetic field-supported cathode sputtering. This is particularly advantageous with regard to simple, quick, economical, and uniform coating of the substrate. However, the electrically conductive layer can also be applied, for example, by vapor deposition, chemical vapor deposition (CVD), plasma-enhanced chemical vapor deposition (PECVD), or by wet chemical methods.

After the application of the electrically conductive layer, the substrate can be subjected to a temperature treatment. The substrate with the electrically conductive layer is heated to a temperature of at least 200° C., preferably at least 300° C. The temperature treatment can serve to increase the transmittance and/or to reduce the sheet resistance of the electrically conductive layer.

After the application of the electrically conductive layer, the substrate can be bent, typically at a temperature from 500° C. to 700° C. Since it is technically simpler to coat a flat pane, this procedure is advantageous if the substrate is to be bent. Alternatively, however, the substrate can also be bent before the application of the electrically conductive layer, for example, if the electrically conductive layer is not suited to withstand a bending process without damage.

The application of the busbar is preferably done by printing and firing an electrically conductive paste in a silkscreen printing process or in an ink-jet process. Alternatively, the busbar can be applied as a strip of an electrically conductive foil onto the electrically conductive layer, preferably applied with contact pressure, soldered, or glued on.

In the case of silkscreen printing methods, the lateral shaping is done by masking the fabric through which the printing paste with the metal particles is pressed. By means of appropriate shaping of the masking, it is, for example, possible to predefine and to vary the width b of the busbar in a particularly simple manner.

The de-coating of individual dividing lines in the electrically conductive layer is preferably done using a laser beam. Methods for patterning thin metal foils are known, for example, from EP 2 200 097 A1 or EP 2 139 049 A1. The width of the de-coating is preferably 10 μm to 1000 μm, particularly preferably 30 μm to 200 μm, and in particular 70 μm to 140 μm. In this range, a particularly clean and residue-free de-coating takes place using the laser beam. Laser-beam de-coating is particularly advantageous since the de-coated lines are visually quite inconspicuous and only little impair the appearance and the view. The de-coating of a line with a width that is wider than the width of a laser incision is done by repeated tracing of the line with the laser beam. Consequently, the processing time and the processing costs increase with increasing line width. Alternatively, the de-coating can be done by mechanical ablation as well as by chemical or physical etching.

An advantageous improvement of the method according to the invention includes at least the following additional steps:

Arranging a thermoplastic intermediate layer on the coated surface of the substrate and Arranging a cover pane on the thermoplastic thermoplastischen intermediate layer, and Bonding the substrate to the cover pane via the thermoplastic intermediate layer.

The substrate is arranged such that the one of its surfaces that is provided with the electrically conductive layer faces the plastic intermediate layer. The surface thus becomes the interior-side surface of the substrate.

The thermoplastic intermediate layer can be formed by one individual thermoplastic film or also by two or more thermoplastic films that are arranged one over another over their entire surface.

The bonding of the substrate and the cover pane is preferably done under the action of heat, vacuum, and/or pressure. Methods known per se for producing a pane can be used.

For example, so-called “autoclave processes” can be performed at a high pressure of roughly 10 bar to 15 bar and temperatures from 130° C. to 145° C. for roughly 2 hours. Vacuum bag or vacuum ring methods known per se operate, for example, at roughly 200 mbar and 80° C. to 110° C. The first pane, the thermoplastic intermediate layer, and the second pane can also be pressed in a calender between at least one pair of rollers to form a pane. Systems of this type for producing panes are known and normally have at least one heating tunnel upstream from a pressing unit. The temperature during the pressing operation is, for example, from 40° C. to 150° C. Combinations of calendering and autoclave methods have proved particularly valuable in practice. Alternatively, vacuum laminators can be used. These consist of one or a plurality of a heatable and evacuable chambers, in which the first pane and the second pane are laminated within, for example, roughly 60 minutes at reduced pressures from 0.01 mbar to 800 mbar and temperatures from 80° C. to 170° C.

In an advantageous embodiment of the method according to the invention, the positioning of the electrically conductive structure and of the illumination means must be selected such that the surface that results from the projection of the illumination means onto the plane of the switch surface is arranged within the switch surface and/or borders the switch surface continuously or discontinuously. In the case of illumination of the light deflection means by a light source on the lateral edge of the substrate, the light source and light deflection means must be positioned such that the zone of the pane irradiated by the light of the light source includes the light deflection means.

The invention also includes the use of the pane having an illuminated switch surface as a functional and/or decorative individual piece and/or as a built-in component in furniture and devices, in particular electronic devices with a cooling or heating function, for glazing of buildings, in particular in the access or window area, or for glazing in a motor vehicle for travel on land, in the air, or on water, in particular in automobiles, buses, streetcars, subways, and trains for passenger service and for public short and long distance travel, for example, as a motor vehicle door or in a motor vehicle door.

The pane according to the invention is particularly advantageously suited for use as a windshield of a passenger vehicle or truck. The driver or front seat passenger can, even in darkness, recognize the illuminated switch surface on the pane and trigger switch operations by simple and convenient touching from the seated position. By means of the switch operation, the heating function of the pane itself can be switched on or off. The illumination means can preferably visualize the switching state of the heating function, for example, by switching the illumination on or off or by changing the color of the illumination or by changing the position of the illumination of the illumination means.

The invention is explained in detail with reference to drawings and exemplary embodiments. The drawings are schematic depictions and not true to scale. The drawings in no way restrict the invention.

They depict:

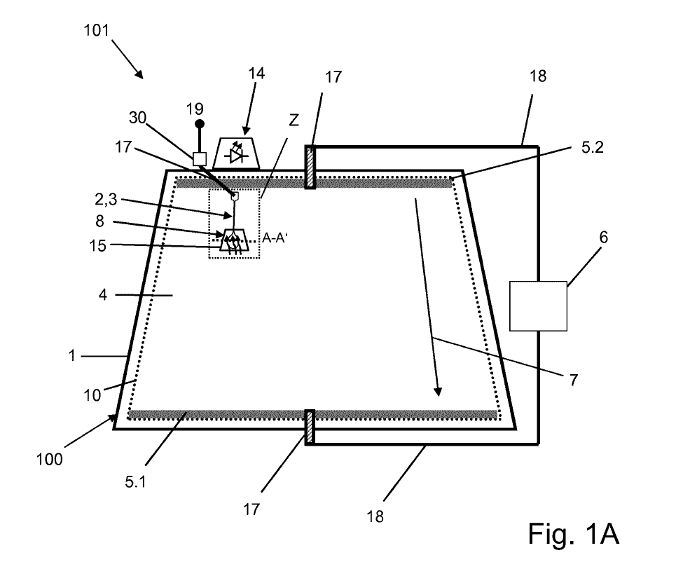

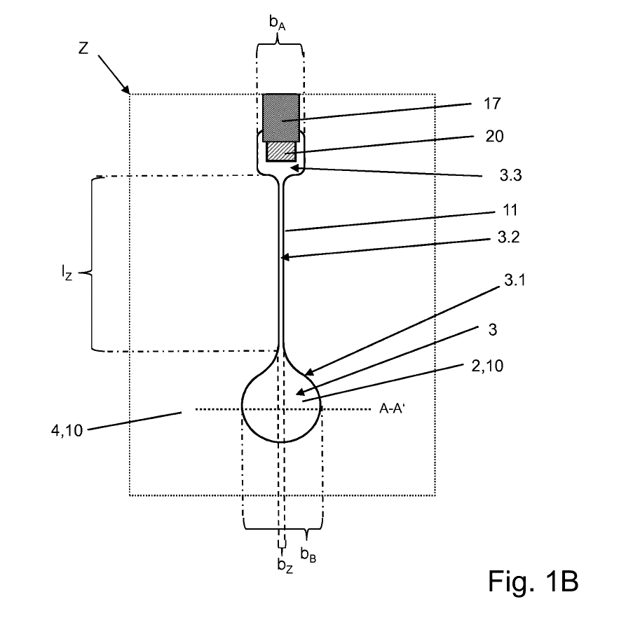

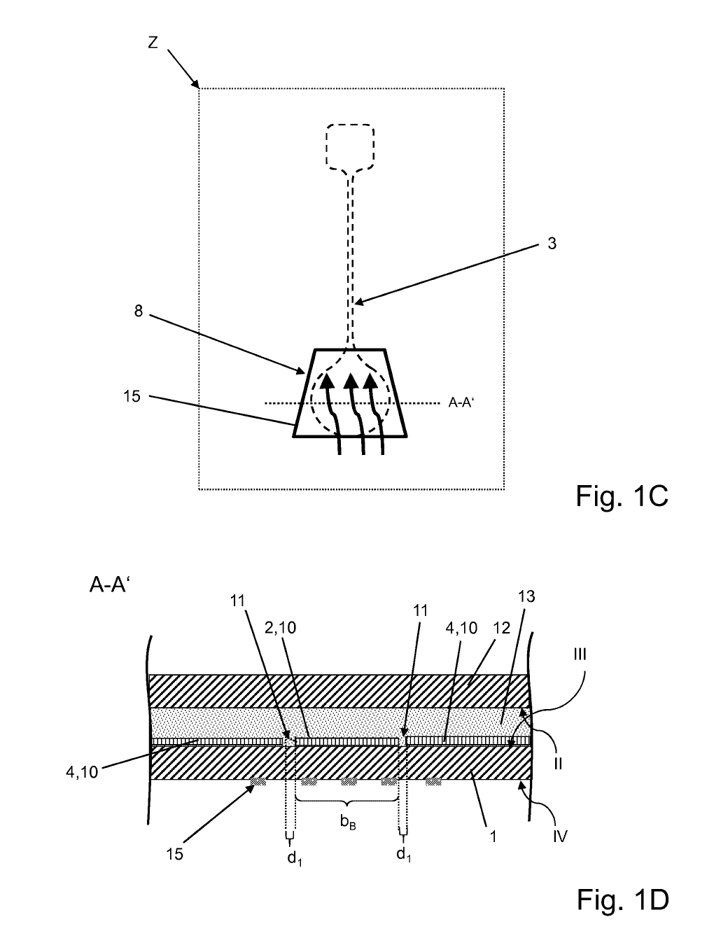

FIG. 1A a top plan view of an embodiment of a pane arrangement according to the invention with a pane according to the invention,

FIG. 1B an enlarged view of the detail Z of FIG. 1A in the plane of the switch surface,

FIG. 1C an enlarged view of the detail Z of FIG. 1A in the plane of the light deflection means,

FIG. 1D a cross-sectional view along the section line A-A′ of FIG. 1A,

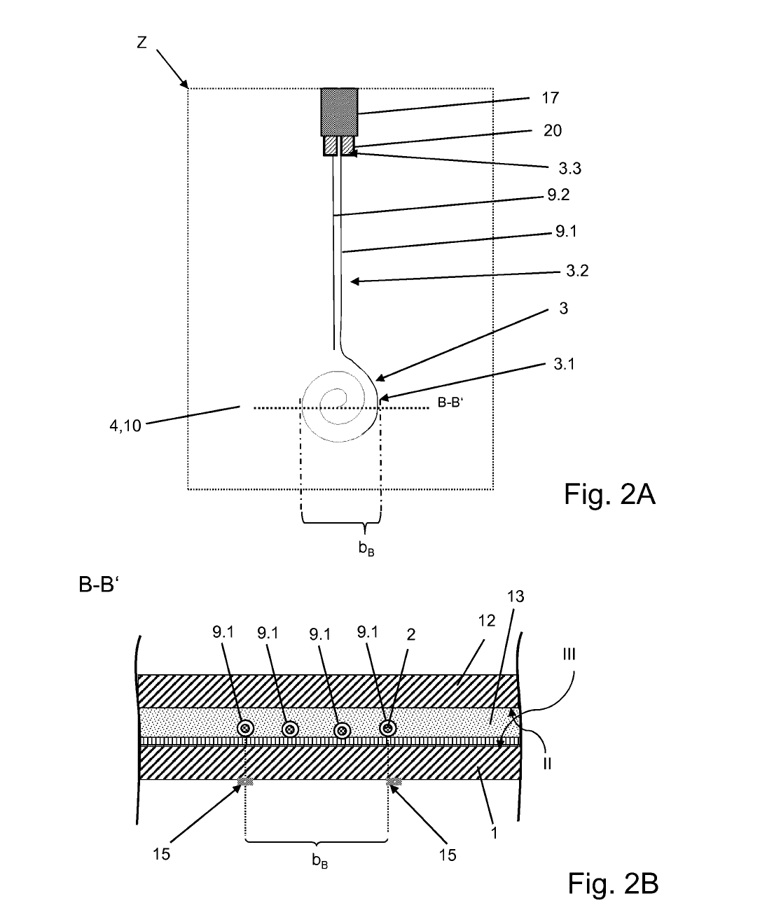

FIG. 2A an alternative embodiment of a pane according to the invention in an enlarged view of the detail Z of FIG. 1A,

FIG. 2B a cross-sectional view along the section line B-B′ of FIG. 2A,

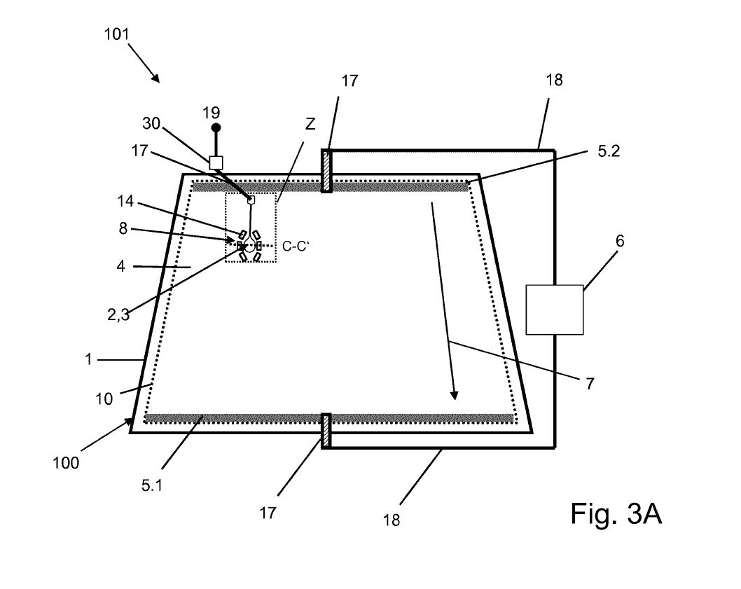

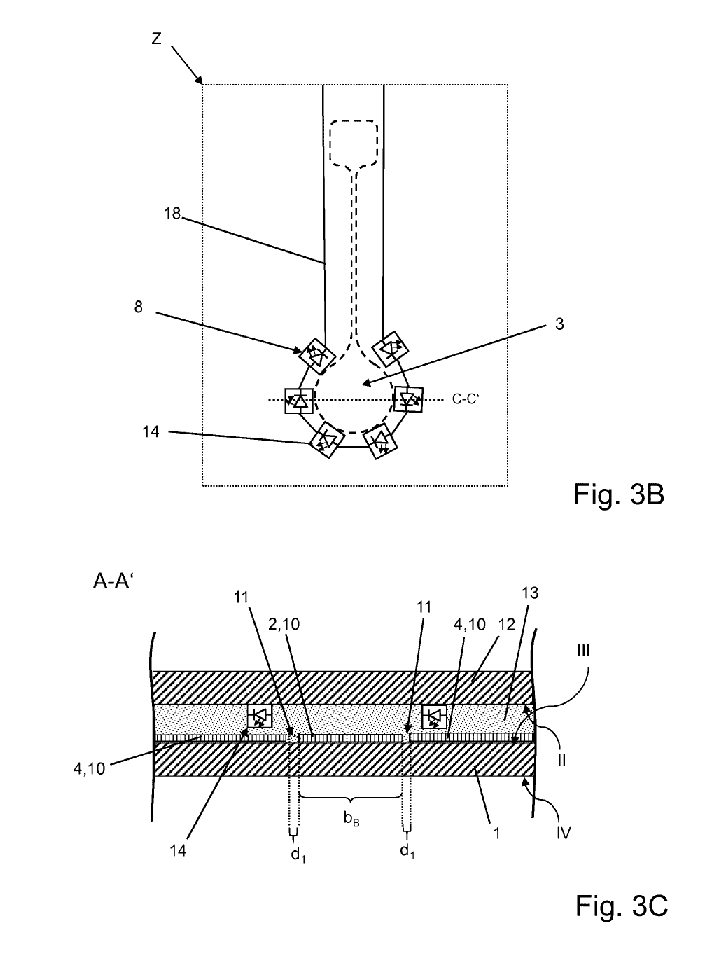

FIG. 3A a top plan view of an alternative embodiment of the pane according to the invention,

FIG. 3B an enlarged view of the detail Z of FIG. 3A,

FIG. 3C a cross-sectional view along the section line C-C′ of FIG. 3A,

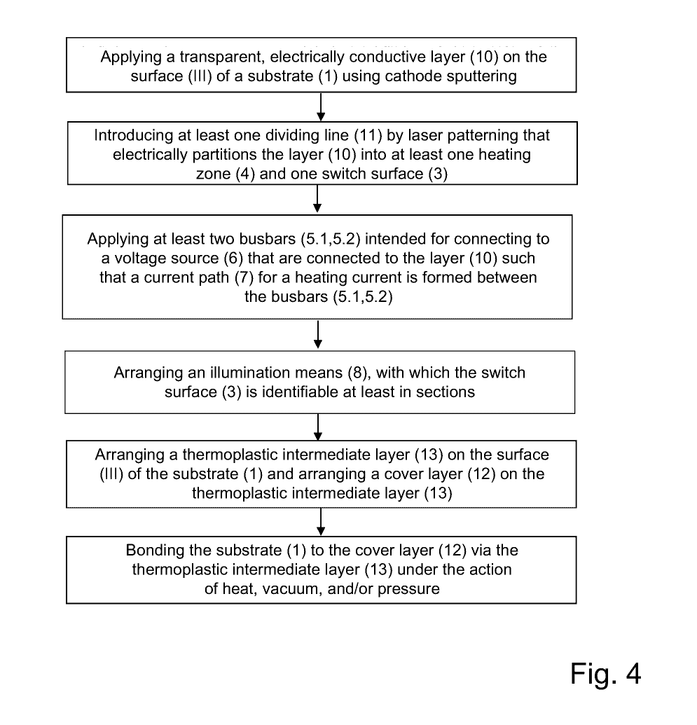

FIG. 4 a detailed flow chart of one embodiment of the method according to the invention.

FIG. 1A depicts a top plan view of an exemplary embodiment of a pane arrangement 101 according to the invention with a pane 100 according to the invention. The pane 100 includes a substrate 1 and is made, for example, of soda lime glass. An electrically conductive layer 10 is applied on a surface III of the substrate 1. The electrically conductive layer 10 is a layer system, which includes, for example, three electrically conductive silver layers that are separated from each other by dielectric layers. When a current flows through the electrically conductive layer 10, it is heated as a result of its electrical resistance and Joule heat generation. Consequently, the electrically conductive layer 10 can be used for active heating of the pane 100. The dimensions of the pane 100 are, for example, 0.9 m×1.5 m.

The electrically conductive layer 10 is partitioned by a dividing line 11 into a heating zone 4 and an electrically conductive structure 2 that forms a switch surface 3. In other words, both the heating zone 4 and the switch surface 3 are made from the electrically conductive layer 10, but are electrically isolated from each other by the dividing line 11. The dividing line 11 only has a width d₁ of, for example, 100 μm and is, for example, introduced into the electrically conductive layer 10 by laser patterning. Dividing lines 11 with such a small width are hardly perceptible and disrupt the view through the pane 100 only little, which is, especially for use in motor vehicles, of particular importance for driving safety.

For the electrical contacting of the heating zone 4, a first busbar 5.1 is arranged in the lower edge zone and another second busbar 5.2 is arranged respectively in the upper edge zone of the heating zone 4. The busbars 5.1, 5.2 contain, for example, silver particles and were applied in the screenprinting method and subsequently fired. The length of the busbars 5.1, 5.2 corresponds approx. to the dimension of the electrically conductive layer 10. The two busbars 5.1,5.2 run approx. parallel.

A light source 14, for example, a light emitting diode (LED), is arranged on the upper lateral edge of the pane 100. In the ON state, the light source 14 can couple light into the substrate 1 via its lateral edge. An illumination means 8 in the form of a light deflection means 15 is arranged on a surface IV of the substrate 1. The light of the light source 14 can leave the substrate 1 via the light deflection means 15 and thus identify the touch zone 3.1 of the switch surface 3. Even two light sources 14 can couple light, with, for example, two different colors, into the substrate 1. The switching state of the heating function can, for example, be visualized via the heating zone by means of the different colors.

FIG. 1B depicts an enlarged view of the detail Z of FIG. 1A in the plane of the switch surface 3. The switch surface 3 includes a touch zone 3.1, which is configured approx. drop-shaped and transitions into a supply line zone 3.2. Here, “drop-shaped” means that the touch zone 3.1 is substantially circular and tapers funnel-like on one side toward the supply line zone 3.2. The width b_{B} of the touch zone 3.1 is, for example, 40 mm. The width b_{Z} of the supply line zone 3.2 is, for example, 1 mm. The supply line zone 3.2 is connected to a connection zone 3.3. The connection zone 3.3 has a square shape with rounded corners and a side length b_{A} of, for example, 12 mm. The length l_{Z} of the supply line zone 3.2 is roughly 48 mm. The ratio b_{Z}:b_{B} is roughly 1:20.

The connection zone 3.3 is electrically conductively connected via an electrical line connection 20 to a foil conductor 17. The foil conductor 17 consists, for example, of a 50 μm thick copper foil and is insulated, for example, outside the connection zone 3.3 with a polyimide layer. Thus, the foil conductor 17 can be guided out beyond the busbar 5.2 over the upper edge of the pane 100 without an electrical short circuit. Of course, the electrical connection of the connection zone 3.3 to the outside can also be guided outward via insulated wires or via a zone in which the busbar 5.2 is interrupted.

Here, the foil conductor 17 is, for example, connected outside the pane 100 to a capacitive sensor electronics assembly 30 that measures the capacitance changes of the switch zone 10 against “ground” and, as a function of the threshold value, forwards a switch signal via the connection point 19, for example, to the CAN [controller area network] bus of a motor vehicle. Any functions in the motor vehicle, for example, even the voltage source 6 and, thus, the electrical heating of the pane 100 via the heating zone 4, can be switched via the switch signal.

FIG. 1 C presents an enlarged view of the detail Z of FIG. 1A in the plane of the light deflection means 15. The light deflection means 15 is arranged on the surface IV of the substrate 1. Here, the light deflection means 15 is implemented, for example, as a roughened spot of the surface IV and has the symbol of a heated windshield. The light deflection means 15 is arranged above the switch surface 3, as seen in the viewing direction, and identifies the touch zone 3.1 of the switch surface 3. The light deflection means 15 can be configured such that it is hardly visible in daylight. Alternatively, the light deflection means 15 can be configured such that it is readily visible in daylight. After the light source 14 is switched ON, light can escape from the substrate 1 via the light deflection means 15 and a user of the pane can readily discern the position of the light deflection means 15 even at night. At the same time or alternatively, information, for example, the switching state of the heating function of the pane can be displayed by the light deflection means 15.

FIG. 1D is a cross-sectional view along the section line A-A′ of FIG. 1A. Here, the pane 100 includes, for example, a substrate 1 and a cover pane 12 that are connected to each other via a thermoplastic intermediate layer 13. The pane 100 is, for example, a motor vehicle window and, in particular, the windshield of a passenger car. The substrate 1 is, for example, intended to face the interior in the installed position. In other words, the side IV of the substrate 1 is accessible from the interior out, whereas, in contrast, side I of the cover pane 12 faces outward. Substrate 1 and cover pane 12 are made, for example, of soda lime glass. The thickness of the substrate 1 is, for example, 1.6 mm and the thickness of the cover pane 12 is 2.1 mm. Of course, substrate 1 and cover pane 12 can have any thicknesses and can, for example, even be implemented with the same thickness. The thermoplastic intermediate layer 13 is made of polyvinyl butyral (PVB) and has a thickness of 0.76 mm. The electrically conductive layer 10 is applied on the interior-side surface III of the substrate 1.

The electrically conductive layer 10 extends, for example, over the entire surface III of substrate 1 minus a circumferential frame-like uncoated zone with a width of 8 mm. The uncoated zone serves for electrical insulation between the voltage-carrying, electrically conductive layer 10 and the motor vehicle body. The uncoated zone is hermetically sealeAusdehnungd to the intermediate layer 8 by gluing in order to protect the electrically conductive layer 10 against damage and corrosion.

For the electrical contacting of the heating zone 4 of the electrically conductive layer 10, a first busbar 5.1 is arranged in the lower edge region and another second busbar 5.2 is arranged in the upper edge region on the electrically conductive layer 2. The busbars 5.1, 5.2 contain, for example, silver particles and were applied by the screenprinting method and subsequently fired. The length of the busbars 5.1, 5.2 corresponds approx. to the dimension of the heating zone 4.

When an electrical voltage is applied to the busbars 5.1 and 5.2, a uniform current flows through the electrically conductive layer 2 of the heating zone 4 between the busbars 5.1,5.2. In roughly the center of each busbar 5.1,5.2, a foil conductor 17 is arranged. The foil conductor 17 is electrically conductively connected to the busbars 5.1,5.2 via a contact surface, for example, by means of a soldering compound, an electrically conductive adhesive, or by simple placement and contact pressure within pane 100. The foil conductor 17 contains, for example, a tinned copper foil with a width of 10 mm and a thickness of 0.3 mm. The busbars 5.1,5.2 are connected via the foil conductor 17 via supply lines 18 to a voltage source 6, which provides onboard voltage customary for motor vehicles, preferably from 12 V to 15 V and, for example, roughly 14 V. Alternatively, the voltage source 6 can also have higher voltages, for example, from 35 V to 45 V and, in particular, 42 V.

The busbars 5.1,5.2 have, in the example depicted, a constant thickness of, for example, roughly 10 μm and a constant specific resistance of, for example, 2.3 μohm·cm.

In a particularly advantageous embodiment of the pane 100 according to the invention, the longitudinal direction of the supply line zone 3.2 of the switch surface 3 has an angle a of, for example, 0.5° relative to the mean direction of the current path 7. Thus, the flow of current of the heating current upon application of a voltage to the busbars 5.1,5.2 is only slightly selected any length without the course of the heating current being appreciably disrupted and without local overheating areas, so-called “hot spots”, developing on the pane 100.

When the pane 100 is used, for example, as a windshield in a motor vehicle, the length of the supply line zone 3.2 can be selected such that the driver of the motor vehicle or the front seat passenger can conveniently reach the touch zone 3.1 of the switch surface 3.

FIG. 2A depicts an alternative embodiment of a pane 100 according to the invention in an enlarged view of the detail Z of FIG. 1A. The switch surface 3 is formed here, for example, by the electrically conductive structure 2 of a metal wire 9.1. The wire 9.1 is bent into a circle on one end and transitions into a spiral with a decreasing radius. There, the wire 9.1 forms a touch zone 3.1. The pane 100 also has a second wire 9.2, which runs parallel to the connection zone 3.2 of the switch surface 3. The wires 9.1,9.2 are electrically connected toward the outside to foil conductors 17 and can connect to a sensor electronics assembly 30. The sensor electronics assembly 30 is, for example, suited to measure a capacitance change between the two wires 9.1,9.2, when the pane 100 is touched in the immediate vicinity of the switch surface 3. The wires 9.1,9.2 have, for example, a diameter of 70 μm and have electrically insulating sheathing. The width b_{B} and the length l_{b} of the touch zone 3.1 is, for example, a maximum of 40 mm. The supply line zone 3.2 is connected to a connection zone 3.3. The remaining structure of the pane 100 corresponds, for example, to the structure of the pane 100 of FIG. 1A.

FIG. 2B depicts a cross-sectional view of the exemplary embodiment according to FIG. 2A along the section line B-B′. The metal wire 9.1 has, for example, an electrically insulating sheathing and is arranged here, for example, between the electrically conductive layer 10 of the heating zone 4 and the intermediate layer 13. By means of the electrically insulating sheathing, a flow of electric current between the wire 9.1 and the heating zone 4 is prevented.

In a particularly advantageous embodiment of the pane 100 according to the invention, the wire can serve as a light deflection means 15 and couple out light, which was coupled into the substrate 1 or the cover pane 12 or an intermediate layer 13.

FIG. 3A depicts an alternative embodiment of a pane arrangement 101 according to the invention with a top plan view of a pane 100 according to the invention, wherein the illumination means 8 are embodied by light sources 14, for example, an LED or an areally arranged OLED-structure, that are arranged directly in the touch zone 3.1 of the switch surface 3. Otherwise, the pane 100 of this exemplary embodiment corresponds, for example, to the pane 100 of FIG. 1A.

FIG. 3B depicts an enlarged view of the detail Z of FIG. 4A. In this exemplary embodiment, six light sources 15 are laminated between the intermediate layer 13 and the cover pane 12. The light sources 15 are guided outward electrically via supply lines 18 and can be connected to a voltage source outside the pane 100.

FIG. 3C depicts for this a cross-sectional view along the section line C-C′ of FIG. 4A. In this exemplary embodiment, the touch zone 3.1 of the switch surface 3 is actively illuminated. Of course, the light sources 15 can also be arranged on the surface I of the cover pane 12 or on the surface IV of the substrate 1 or in recesses of the substrate 1 or of the cover pane 12.

In a particularly advantageous embodiment of the pane 100 according to the invention, the electrically conductive layer 10 is partitioned by additional dividing lines that form supply lines 18, to which the light sources 14 are electrically connected among each other and toward the outside.

Of course, the exemplary embodiments depicted here can also be configured as a heating zone with individual heating wires that connect the busbars 5.1 and 5.2 instead of a heating zone 4 with an electrically conductive layer 10.

FIG. 4 depicts a flowchart of an exemplary embodiment of the method according to the invention for producing an electrically heatable pane 100 with a switch zone 10.

The pane according to the invention 100 according to FIG. 1-3 has a switch surface 3 that can be connected, for example, to a capacitive sensor electronics assembly 30. At the same time, the pane 100 has an electrically heatable heating zone 4, wherein the heating function and heating power distribution is only slightly impaired or not all impaired by the switch surface 3.

This result was unexpected and surprising for the person skilled in the art.

### LIST OF REFERENCE CHARACTERS

100 pane with an illuminated switch surface
101 pane arrangement
1 transparent substrate
2 electrically conductive structure
3 switch surface
3.1 touch zone
3.2 supply line zone
3.3 connection zone
4 heating zone
5.1, 5.2 busbars
6 voltage source
7 current path
8 illumination means
9.1,9.2 wire
10 electrically conductive layer
11 dividing line
12 cover pane
13 intermediate layer
14 light source (LED)
15 light deflection means
16 sensor electronics assembly
17 flat conductor
18 supply line
19 connection point
20 electrical line connection
30 sensor electronics assembly
II surface of the cover pane 12
III surface of the substrate 1
IV surface of the substrate 1
b_{A} width of the connection zone 3.3
b_{B} width of the touch zone 3.1
b_{Z} width of the supply line zone 3.2
d₁ width of the dividing line 11
l_{A} length of the connection zone 3.3
l_{B} length of the touch zone 3.1
l_{Z} length of the supply line zone 3.2
A-A′ section line
B-B′ section line
C-C′ section line
Z detail

1.-16. (canceled)

17. A pane with an illuminated switch surface and a heating function, the pane comprising:
a transparent substrate;
a heating zone connected to at least two busbars, provided for connection to a voltage source, so as to form a current path for a heating current between the at least two busbars;
an electrically conductive structure that forms a switch surface and that is adapted for connection to a sensor electronics assembly; and
an illumination means configured to mark the switch surface.

18. The pane according to claim 17, wherein the substrate is bonded via at least one intermediate layer to a cover pane.

19. The pane according to claim 18, wherein the intermediate layer comprises one or more of: a) polyvinyl butyral (PVB) and b) ethylene vinyl acetate (EVA).

20. The pane according to claim 17, wherein the heating zone comprises a transparent and electrically conductive layer.

21. The pane according to claim 20, wherein the electrically conductive structure and the heating zone are electrically isolated from the transparent and electrically conductive layer by at least one dividing line.

22. The pane according to claim 17, wherein the heating zone comprises one of: a) at least one heating wire, and b) at least one printed heating structure, made of an electrically conductive material.

23. The pane according to claim 17, wherein the electrically conductive structure comprises at least one linearly shaped electrically conductive element.

24. The pane according to claim 23, wherein the at least one linearly shaped electrically conductive element is a metal wire with a diameter of ≦0.25 mm.

25. The pane according to claim 17, wherein the illumination means comprises one of: a) a light source, and b) an LED or an OLED.

26. The pane according to claim 25, wherein the light source couples light into one or more of: a) the substrate, b) the intermediate layer, and c) the cover pane.

27. The pane according to claim 25, wherein the light source emits light directly outward out of the pane.

28. The pane according to claim 25, wherein the light source is arranged according to one of: a) laminated between the substrate and the cover pane, b) arranged on the outer side of the substrate or the outer side of the cover pane, and c) arranged in an opening in the substrate or in the cover pane.

29. The pane according to claim 25, wherein the light source is arranged in an immediate vicinity of the switch surface.

30. The pane according to claim 25, further comprising at least one light deflection means, wherein:
the at least one light deflection means is arranged in a zone of one of: a) the substrate, b) the intermediate layer, and c) of the cover pane irradiated by the light of the light source,
the at least one light deflection means comprises at least one structure for light scattering arranged in an immediate vicinity of the switch surface, and
the at least one light deflection means couples light out of the substrate, the intermediate layer, or the cover pane.

31. The pane according to claim 30, wherein the at least one structure for light scattering comprises one or more of: a) particles, b) point grids, c) stickers, d) deposits, e) indentations, f) scratches, g) line grids, h) imprints, and i) silkscreen prints.

32. The pane according to claim 25, wherein the light source comprises two power supply connectors adapted for connection to a voltage source via electrical supply lines.

33. The pane according to claim 32, wherein the electrical supply lines are electrically isolated from the electrically conductive layer by dividing lines.

34. The pane according to claim 32, wherein the two power supply connectors are connected to the voltage supply of the heating zone via wires or via a part of the electrically conductive layer.

35. A pane arrangement, comprising:
the pane according to claim 17;
at least one sensor electronics assembly; and
at least one voltage source electrically connected to the switch surface, to the heating zone, and to the illumination means,
wherein responsive to a touch of the switch surface by a person:
the sensor electronics assembly is configured to issue a switch signal for controlling the heating function of the pane, and
the illumination means displays a switching state of the heating function.

36. A method for producing a pane with an illuminated switch surface and a heating function, the method comprising:
applying an electrically conductive layer on a surface of a transparent substrate;
forming at least one dividing line to electrically partitioning the electrically conductive layer into at least one heating zone and at least one electrically conductive structure, thereby forming a switch surface;
providing at least two busbars adapted for connecting to a voltage source, and connecting he at least two busbars to the electrically conductive layer of the heating zone, thereby forming between the at least two busbars a current path for a heating current; and
providing an illumination means for identifying the switch surface, at least in sections.

37. A method, comprising:
using the pane according to claim 17, in one or more of: a) as a functional piece, b) as a decorative individual piece, c) as a built-in component in furniture and devices, d) in electronic devices with a cooling or heating function, e) for glazing of buildings, f) in and access or window area, g) for glazing in a motor vehicle for travel on land, in the air, or on water, h) in automobiles, buses, streetcars, subways, and trains for passenger service and for public short and long distance travel, i) as a motor vehicle door and, j) as a windshield.
